(19) United States
(12) Patent Application Publication
(10) Pub. No.: US 2001/0017395 A1
(43) Pub. Date: Aug. 30, 2001

(54) Inductors, semiconductor devices, and methods of manufacturing semiconductor devices

(76) Inventor: Takashi Takamura, Chind-shi (JP)

Correspondence Address: Konrad Raynes & Victor, LLP, Suite 210, 315 South Beverly Drive, Beverly Hills, CA, 90212, US

(21) Appl. No.: 09/735,737

(22) Filed: Dec. 13, 2000

(30) Foreign Application Priority Data
Dec. 13, 1999 (JP) 11-353070

(51) Int. Cl. H01L 29/00

(52) U.S. Cl. 257/531

(57) ABSTRACT

Certain embodiments relate to an inductor that can be manufactured with the existing manufacturing facility, and greatly contributes to a further miniaturization of apparatuses. Embodiments include a semiconductor device having an inductor 100 and a CMOSFET 200 on a SOI. The inductor 100 is obtained by conducting a photolithography and an etching on a cobalt thin film formed on the LOCOS film 6.

Japanese patent application no. 11-353070, filed Dec. 13, 1999, is hereby incorporated by reference in its entirety. U.S. patent application Ser. No , ______ filed on Dec. 13, 2000, entitled “Semiconductor Devices,” invented by Takashi Takamura, docket no. 15.25/5310, is hereby incorporated by reference in its entirety.

### TECHNICAL FIELD

The present invention relates to inductors such as coils and transformers (i.e., circuits having inductance) and semiconductor devices having the same.

### BACKGROUND

In conventional art, since it is difficult to form inductors within an integrated circuit, such as a high frequency circuit, a DC-DC converter, an inductor is provided external to the integrated circuit. However, in recent years, techniques to form inductors within an integrated circuit are sought in order to further miniaturize appliances and lower the cost.

A technique to form an inductor within an integrated circuit is described in Japanese Laid-open patent application HEI 9-7834. The publication describes a monolithic microwave integrated circuit having a ferromagnetic thin-film inductor. The ferromagnetic thin-film inductor includes ferrite (insulating ferromagnetic oxide material) thin films formed by a laser ablation method immediately above and below a thin film coil.

However, the technique in the above-described publication uses a laser ablation method that is not performed in an ordinary process for manufacturing integrated circuits. Therefore, there is a problem that a facility investment is required. Also, the ferrite thin-film inductor described in the publication has a three-layer structure formed from a thin film coil and ferrite thin films above and below the thin film coil. As a result, a further improvement is required for device-miniaturization.

### SUMMARY

Certain embodiments of the present invention relate to an inductor comprising a pattern formed with a thin film of ferromagnetic metal material.

One embodiment relates to a method for manufacturing a semiconductor device, including forming a pattern for an inductor by conducting photolithography and etching a thin film of ferromagnetic metal material.

Another embodiment relates to a method for manufacturing a semiconductor device, including forming a layer of ferromagnetic material in direct contact with an insulating layer, a silicon layer, and a gate electrode layer. The ferromagnetic material is heated to form a silicide layer where the ferromagnetic material is in direct contact with the silicon layer and the gate electrode layer. The ferromagnetic material is etched to form an inductor on the insulating layer.

Another embodiment relates to a method for forming a semiconductor device including a field effect transistor and an inductor, including forming a layer of ferromagnetic material in direct contact with an insulating layer. The ferromagnetic layer is patterned and etched to form an inductor on the insulating layer. An opening is formed in a silicon substrate positioned under the insulating layer so that the opening in the silicon substrate is positioned under the inductor.

Another embodiment relates to an inductor consisting of a thin film of ferromagnetic material.

In addition, certain embodiments preferably include a single ferromagnetic layer inductor including from a material selected from the group consisting of cobalt, iron and nickel.

### BRIEF DESCRIPTION OF THE DRAWINGS

Certain embodiments of the invention are described with reference to the accompanying drawings which, for illustrative purposes, are schematic and not necessarily drawn to scale.

FIG. 1 illustratively shows a cross section of a semiconductor device in accordance with one embodiment of the present invention.

FIG. 2 illustrates a method for manufacturing the semiconductor device shown in FIG. 1.

FIG. 3 illustratively shows a cross section of a semiconductor device in accordance with another embodiment of the present invention.

### DETAILED DESCRIPTION OF INVENTION

Certain embodiments of the present invention have been made in view of such technical problems of the conventional technology described above. Certain embodiments provide an inductor that can be manufactured with the currently existing facility, and greatly contributes to the miniaturization of devices including appliances.

Certain embodiments of the present invention provide an inductor composed of a pattern formed with a thin film of ferromagnetic material. To reduce current loss, the ferromagnetic material preferably has a specific resistance of 300 Ωcm or less at room temperature. Also, the ferromagnetic material is preferably any one of cobalt (Co), iron (Fe) and nickel (Ni). More preferably, the ferromagnetic material is cobalt (Co).

Furthermore, certain embodiments of the present invention provide a semiconductor device in which an inductor formed in an integrated circuit is composed of a pattern formed with a thin film of ferromagnetic material.

In accordance with certain embodiments of the present invention, a semiconductor device is preferably obtained by continuously forming a thin film of ferromagnetic material on an insulation layer on which an inductor is formed, an electrode and a silicon layer forming a source/drain region, then forming a pattern of the inductor with the thin film, and then forming a silicide layer of ferromagnetic material above the gate electrode and the source/drain region.

Also, certain embodiments of the present invention provide a semiconductor device comprising an inductor formed over a silicon substrate through an insulation layer, wherein the silicon substrate has a lower section defining a through hole formed below an area where the inductor is formed, the through hole being formed by an etching from rear side of the silicon substrate, and being in an insulating state.

Embodiments of the present invention also include methods for manufacturing semiconductor devices including a step of forming a pattern for an inductor by conducting photolithography and etching a thin film of ferromagnetic material.

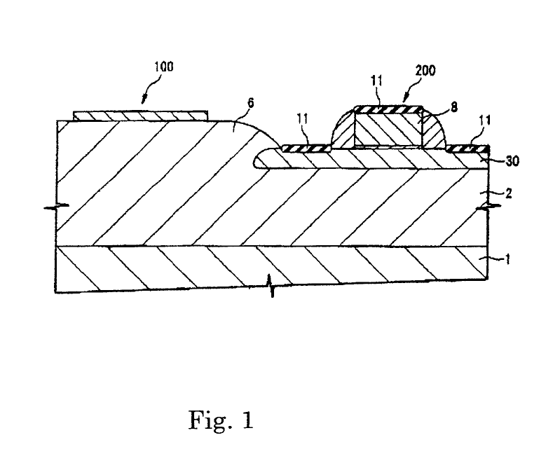

Certain embodiments of the present invention will be described below with reference to FIGS. 1-3.

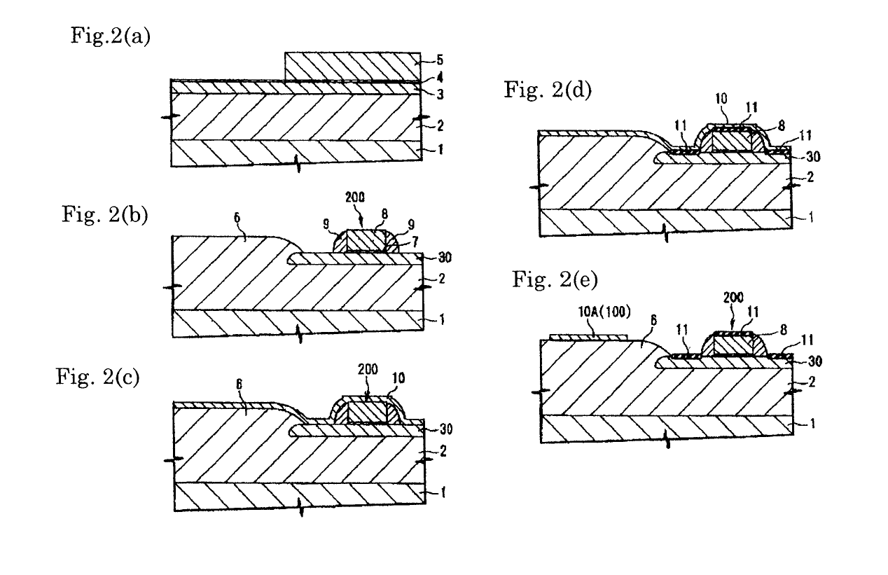

FIG. 1 schematically shows a cross section of a semiconductor device in accordance with one embodiment of the present invention. The semiconductor device has an integrated circuit including an inductor 100 and CMOSFET (complementary metal-oxide semiconductor field effect transistor) 200 on an SOI (Silicon on insulator). A method for manufacturing the semiconductor device is described with reference to FIG. 2.

As shown in FIG. 2(a), the SOI normally includes a silicon substrate 1, a silicon oxide film 2 and a monocrystal silicon film 3 in this order. A thin oxide film 4 is formed on the monocrystal silicon film 3, and a mask 5 composed of a silicon nitride film is formed on the thin oxide film 4. In this state, exposed portions of the thin oxide film 4 are removed, and exposed portions of the monocrystal silicon film 3 are thermally oxidized, to thereby form LOCOS films 6 at an element isolation position and in a region where an inductor 100 is formed. The LOCOS film 6 connects to the silicon oxide film 2 below, as shown in FIG. 2(b).

Next, an impurity is doped in an element region 30 that is isolated by the LOCOS film 6, a gate oxide film 7 is formed, a gate electrode 8 composed of polysilicon is formed, impurity doping for forming an LDD (Lightly Doped Drain) region is conducted, sidewalls 9 are formed, and impurity doping is conducted in source and drain regions. As a result, the CMOSFET 200 is formed on the SOI. Each of the steps may be conducted according to the conventionally known method. FIG. 2(b) shows a state in which the above-described steps have been conducted. Referring to FIG. 2(b), either one of p-channel MOSFET and n-channel MOSFET that form the CMOSFET 200 is omitted.

Then, a thin film 10 composed of cobalt (Co) is formed by a sputtering method over the entire surface of the silicon substrate 1 in the state shown in FIG. 2(b). FIG. 2(c) shows a state in which the above-described processes have been conducted. The cobalt thin film 10 may have a film thickness of about 0.05 μm, for example,

Then, the silicon substrate 1 in the state shown in FIG. 2(c) is thermally treated for a specified period of time at a temperature of about 700° C. As a result, the cobalt thin film 10 on the gate electrode 8 and an element region 30 (source/drain region), polysilicon on the gate electrode 8 and the monocrystal silicon of the element region 30 react with one another, and a CoSi layer (silicide layer) 11 is formed. FIG. 2(d) shows this state.

Next, a photoresist film is formed on the cobalt thin film 10, and the photoresist film is subject to an ordinary photolithography step to thereby form a resist pattern. The resist pattern has portions of the photoresist that correspond to a coil pattern defining an inductor, and other portions where the photoresist is removed. Then, a solution including a mixed liquid of aniline hydrochloride and hydrogen peroxide, as a main composition, is used to etch the cobalt thin film 10. As a result, a coil pattern (an inductor pattern) 1OA composed of the cobalt thin film is formed. Also, the CoSi layer 11 on the gate electrode 8 and the element region 30 is exposed. FIG. 2(e) shows this state.

Then, to activate the impurity doped in the source and drain region, a thermal treatment is conducted at 1000° C. for 20 seconds. The melting point of cobalt is 1490° C., and therefore it can withstand the thermal treatment. If required, an interlayer dielectric film may be formed on the wafer in this state, a cobalt thin film is further formed thereon, and an ordinary photolithography process and an etching process are conducted for the cobalt thin film, to thereby form an inductor pattern composed of the cobalt thin film.

The inductor 100 composed of the cobalt thin film in the semiconductor device thus obtained provides excellent coil characteristics without a magnetic core. This is because, although cobalt has a resistance relatively higher than aluminum, its magnetic permeability is substantially higher. Ferromagnetic materials other than cobalt, such as, iron (Fe) and nickel (Ni) have similar characteristics. Therefore, iron or nickel may be used instead of cobalt. However, since cobalt is a material that is commonly used in semiconductor manufacturing processes, and its affinity to the ordinary semiconductor manufacturing process is strong, the use of cobalt is most preferable.

The semiconductor device of certain embodiments of the present invention has the inductor 100 that is formed from a cobalt thin film in one layer. Therefore, the size of an integrated circuit can be made smaller than that of the circuit having an inductor of a three-layer structure described in the publication described above. Also, the resistance of the gate 8 and the source and drain region can be reduced by the CoSi layer 11. Further, the inductor pattern can be formed with the cobalt thin film by conducting a lithography step and an etching step which are normally conducted in a wiring formation process. Therefore, a facility investment is not required.

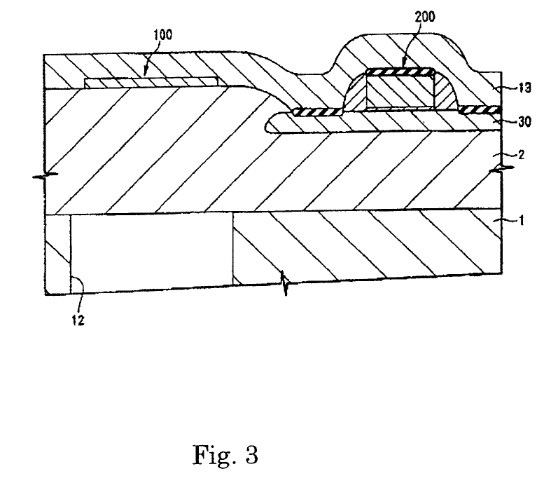

Another embodiment of the present invention is shown in FIG. 3. A semiconductor device includes a silicon substrate 1 and an inductor 100. A through hole 12 is formed in the silicon substrate 1 in a portion below an area where the inductor 100 is formed. The through hole 12 preferably has a cross-sectional area that is slightly larger than the inductor 100. The through hole 12 may be formed by etching the silicon substrate 1 from its rear side after a silicon oxide film 13 is formed on the silicon substrate 1 in the state shown in FIG. 2(e).

More specifically, a silicon oxide film is formed by a CVD method on a rear surface of the silicon substrate 1. Then, a resist pattern is formed on the silicon oxide film. The resist pattern defines a portion in which the resist is removed at a location corresponding to the through hole 12. Then, the silicon oxide film and the silicon substrate 1 are etched, using the resist pattern as a mask. Since the difference in etching speed between silicon and silicon oxide (selection ratio) is substantially large, a deep hole with a high aspect ratio can be formed in the silicon substrate 1 as a result of the provision of the silicon oxide film. The silicon substrate 1 is etched by a dry etching method, using a gas, such as a gas mainly containing a chlorine gas.

The through hole 12 may be filled with an insulation material such as polyimide resin, or silicon oxide, or not be filled with anything. As a result, when the semiconductor device is cut as a semiconductor chip and enclosed in a package, the interior of the through hole 12 is kept in an insulating state.

By the presence of the through hole 12, electrical interference between the inductor 100 and the silicon substrate 1 is inhibited or prevented, with the result of that parasitic capacitances is reduced. Accordingly, when the inductor 100 is a high-frequency coil or a high-frequency transformer, a high-frequency amplification circuit with a high performance and a low loss is obtained.

As described above, the semiconductor device may have CoSi (silicide) layers 11 above the gate electrode 8 and the source and drain region. However, the present invention is not limited to these semiconductor devices having such silicide layers.

Also, as described above, the cobalt thin film 10 for forming the CoSi layer 11 may be continuously formed on the LOCOS film (insulation layer) 6 on which the inductor 100 is formed, and an inductor pattern is formed with the cobalt thin film 10. However, a thin film for an inductor may be provided independently of a thin film for a silicide layer. In this case, although the number of manufacturing steps may slightly increase, a thin film of cobalt or the like can be formed to have an optimum thickness for an inductor. Therefore, such a thin film can, for example, be made thicker than a thin film for a silicide layer, such that an inductor having a lower resistance is obtained.

As described above, certain embodiments of the present invention may provide the following effects. An inductor can be manufactured by the existing facility, and the size of an integrated circuit can be reduced, in contrast to inductors having a three-layered structure described in the publication described above.

By using a semiconductor device in accordance with certain embodiments of the present invention, an apparatus having a circuit that includes inductors can be made substantially smaller.

Also, by using a method in accordance with certain embodiments of the present invention, inductors can be manufactured by using the existing facility. Therefore, the method is suitable for manufacturing a semiconductor device of the present invention. It should be appreciated that various modifications may be made while remaining within the scope of embodiments of the present invention.

What is claimed:

1. An inductor comprising a pattern formed with a thin film of ferromagnetic metal material.

2. An inductor according to claim 1, wherein the ferromagnetic metal material has a specific resistance of 300 Ωcm or less at room temperature.

3. An inductor according to claim 1, wherein the ferromagnetic metal material is one of cobalt (Co), iron (Fe) and nickel (Ni).

4. An inductor according to claim 1, wherein the ferromagnetic metal material is cobalt (Co).

5. An inductor according to claim 1, wherein the inductor comprises a single layer of the ferromagnetic material.

6. A semiconductor device comprising an inductor formed in an integrated circuit in accordance with of claim 1.

7. A semiconductor device according to claim 6,
the semiconductor device obtained by forming a thin film of ferromagnetic metal material on an insulation layer on which an inductor is formed, a gate electrode and a silicon layer forming a source/drain region,
forming a pattern of the inductor with the thin film, and
forming a silicide layer of ferromagnetic metal material above the gate electrode and the source/drain region.

8. A semiconductor device comprising an inductor according to claim 1 formed over a silicon substrate through an insulation layer, the silicon substrate having an upper side on which the insulation layer is formed and a lower side opposite the upper side, wherein the silicon substrate defines a through hole formed below an area where the inductor is formed, the through hole being formed by etching from the lower side towards the upper side of the silicon substrate, and the through-hole defining a region in an insulating state.

9. A method for manufacturing a semiconductor device, comprising forming a pattern for an inductor by conducting photolithography and etching a thin film of ferromagnetic metal material.

10. A method as in claim 9, wherein the inductor includes a single layer of the ferromagnetic metal material.

11. A method as in claim 9, wherein the inductor consists of a single layer of the ferromagnetic metal material.

12. A method as in claim 11, wherein the ferromagnetic metal material comprises a material selected from the group consisting of cobalt, iron and nickel.

13. A method as in claim 9, wherein the ferromagnetic material comprises cobalt.

14. A method for manufacturing a semiconductor device, comprising:
forming a layer of ferromagnetic material in direct contact with an insulating layer, a silicon layer, and a gate electrode layer;
heating the ferromagnetic material to form a silicide layer where the ferromagnetic material is in direct contact with the silicon layer and the gate electrode layer; and
etching the ferromagnetic material to form an inductor on the insulating layer.

15. A method as in claim 14, further comprising forming an opening in a silicon substrate positioned under the insulating layer so that the opening in the silicon substrate is positioned under the inductor.

16. A method as in claim 15, wherein the inductor comprises a single layer of the ferromagnetic material.

17. A method as in claim 16, wherein the ferromagnetic material is a metal.

18. A method as in claim 16, wherein the ferromagnetic material is selected from the group consisting of cobalt, iron and nickel.

19. A method as in claim 15, further comprising filling the opening in the silicon substrate with an insulating material.

20. A method as in claim 19, wherein the insulating material filling the opening comprises a material selected from the group consisting of a polyimide and silicon oxide.

21. A method for forming a semiconductor device including a field effect transistor and an inductor, comprising:
forming a layer of ferromagnetic material in direct contact with an insulating layer;
patterning and etching the ferromagnetic material to form an inductor on the insulating layer; and
forming an opening in a silicon substrate positioned under the insulating layer so that the opening in the silicon substrate is positioned under the inductor.

22. A method as in claim 21, further comprising filling the opening with an insulating material.

23. A method as in claim 21, wherein the inductor comprises a single layer of the ferromagnetic material etched in a coil shape.

24. A method as in claim 21, wherein the ferromagnetic material is a metal.

25. An inductor consisting of a thin film of ferromagnetic material.
